(19) United States
(12) Patent Application Publication
(10) Pub. No.: US 2011/0188197 A1
(43) Pub. Date: Aug. 4, 2011

(54) INTEGRATED AUDIO AND VIDEO PORT FOR PORTABLE ELECTONIC DEVICES

(76) Inventor: Craig Jackson, Austin, TX (US)

(21) Appl. No.: 12/699,479

(22) Filed: Feb. 3, 2010

(51) Int. Cl. H05K 5/00

(52) U.S. Cl. 361/679.41

(57) ABSTRACT

A docking assembly for receiving a portable electronic device. The docking assembly includes a housing unit containing a portion of a vehicle electronic system and a docking port. The docking port is configured to electrically couple a portable electronic device (PED) to the vehicle electronic system, and to mechanically couple the PED to the housing unit. When the PED is coupled to the vehicle electronic system, it may provide audio signals thereto, and may also provide video and/or other types of signals. The PED may also control one or more functions of the vehicle electronic system when coupled thereto via the docking port.

### BACKGROUND OF THE DISCLOSURE

1. Field of the Invention

This invention relates to portable electronic devices, and more particularly, to a port for receiving a portable electronic device.

2. Description of the Related Art

In recent years, there has been a proliferation of portable electronic devices. Such devices may include telephones, music and media players, personal digital assistants (PDA's), devices for accessing the Internet, and navigation devices (e.g., Global Positioning System, or GPS, devices), among other functions. In many cases, such devices may incorporate the functionality of multiple ones of the devices discussed above, as well as numerous other functions not listed herein. For example, portable electronic devices that incorporate the functionality of a telephone, a navigation device, and Internet access device, and multimedia playback (e.g., audio and/or video) device are common.

Such portable electronic devices are typically compact in size such that they may be easily held and operated in the hands of a user. Accordingly, many portable electronic devices are capable of incorporating a wide variety of functions in a highly portable unit. In large part due to the portability of the types of devices, users may utilize the functions provided thereby in a wide variety of environments. For example, a user that is moving between two different locations may take a phone call, listen to music, access the internet, or access direction via a GPS system using a portable electronic device. Furthermore, the utilization of such functions may performed “on the go”, e.g., when the user is walking.

### SUMMARY OF THE DISCLOSURE

A vehicle docking assembly is disclosed. In one embodiment a vehicle docking assembly includes a housing unit and a docking port. The housing unit may also be suitable for mounting in a vehicle. The housing unit may include a first portion of a vehicle electronic system that includes at least one functional unit configured to be coupled to a corresponding unit of a second portion of the vehicle electronic system. The vehicle docking assembly may also include a docking port coupled to the housing unit. The docking port may include an electrical connector configured to couple a portable electronic device (PED) to the vehicle electronic system. The docking port may also mechanically couple the PED to the housing unit. The first portion of the vehicle electronic system may be configured to receive audio signals from the PED when the PED is electrically coupled thereto.

In one embodiment, the docking assembly is integrated into the dashboard of an automobile or other vehicle. The PED that may be coupled thereto may be a cellular phone, a portable multimedia (e.g., audio and/or video) player, a personal digital assistant (PDA) configured for wireless access to the internet, a navigation device (e.g., a unit configured to utilize the global positioning system, or GPS, to provide directions), and so forth. In some embodiments, a PED configured to coupling to the docking assembly may provide a combination of the functions of the devices listed above. Such a combination may include some or all of the functions listed above, as well as other functions not specifically mentioned. The functions provided by the portable electronic device may utilize the vehicle electronic system. For example, in one embodiment, an audio player in a portable electronic device may, when electrically coupled to the vehicle electronic system, provide audio signals that are output as sound by one or more speakers of the vehicle. In another embodiment, a PED may output video signals to the vehicle electronic system, wherein the video signals are then provided to a video display unit within the vehicle.

In one embodiment the housing may be a DIN (Deutsches Institut für Normung, or, in English, the German Institute for Standardization) unit within the vehicle dashboard. The DIN unit may be a single DIN unit in some embodiments, a double DIN unit in other embodiments, or a 1.5 DIN unit (i.e. 1.5 times the size of a single DIN unit). Embodiments that conform to other sizes and/or specifications are also possible and contemplated. In embodiments where they are utilized, a DIN unit (or double DIN unit or 1.5 DIN unit) may provide housing for at least a first portion of the vehicle electronic system.

As used herein, the term ‘dashboard’ may refer to the dashboard of an automobile. However, the term ‘dashboard’ as used herein may also refer to an instrument panel in an aircraft, watercraft, or any type of land vehicle. In general, the term ‘dashboard’ as used herein may refer to any panel within reach of an operator of the vehicle. Furthermore, as will be discussed below, embodiments of the docking assembly may be placed in other locations within a vehicle.

In one embodiment, a first portion of the vehicle electronic system to which the PED may be coupled may include a power/charging circuit, an audio transmission unit, an audio amplifier, a video transmission unit, and a tone control unit, in addition to the docking port. The audio transmission unit may receive audio signals (in analog or digital format) from the portable electronic device (by way of a tone control unit in some embodiments) and provide these audio signals to one or more speakers via an audio amplifier. Similarly, the video transmission unit may receive video signals from the portable electronic device, may format these signals for display, and subsequently transmit the formatted video signals to a video display unit in the vehicle.

Thus, the vehicle docking assembly described herein may allow a PED to utilize the vehicle electronic system to perform various functions. For example, a user having a PED having a number of audio files (e.g., songs) stored thereon (e.g., in .mp3 format) may play these audio files in the vehicle, utilizing the vehicle's speakers for audio output. A user having video files stored on a portable electronic device may play these files utilizing an in-vehicle video display unit to display the resulting video. The speakers in the automobile may also be used to output audio signals from a phone call when the portable electronic device is operating as a cell phone.

Since the PED may play music and other audio, it may, in combination with the vehicle docking assembly, replace a typical head unit of a car stereo or similar unit in another type of vehicle. Moreover, a majority of the functionality that is provided by a head unit may be replaced by the functionality provided by the PED. For example, whereas a head unit may provide music/audio playing functionality via a CD (compact disk) player or cassette player in a head unit. Similarly, the ability of a PED to play back video files may replace the functionality of a DVD (digital video disk) player in a head unit. In general, various embodiments of a PED may be able to replace some or all of the functionality provided by various embodiments of a head unit. The functionality of the PED may be provided through hardwired connections in the vehicle docking assembly, thus obviating the need to transmit wireless signals to the vehicle electronic system. Furthermore, since the vehicle docking assembly disclosed herein is designed to allow easy insertion and removal of the PED from the docking port, the PED may be taken with the user when the user departs the vehicle.

### BRIEF DESCRIPTION OF THE DRAWINGS

Other aspects of the invention will become apparent upon reading the following detailed description and upon reference to the accompanying drawings in which:

FIG. 1 is an illustration of one embodiment of a portable electronic device coupled to a docking assembly;

FIG. 2 is a top view of one embodiment of a docking port having a portable electronic device inserted therein;

FIG. 3A is a top view of one embodiment of a docking port without a portable electronic device inserted therein;

FIG. 3B is a top view of one embodiment of a docking assembly with a portable electronic device coupled thereto;

FIG. 3C is a top view of another embodiment of a docking assembly with a portable electronic device coupled thereto;

FIG. 4A is a block diagram of one embodiment of a vehicle electronic system with an embodiment of a portable electronic device coupled thereto;

FIG. 4B is a block diagram of another embodiment of a vehicle electronic system with an embodiment of a portable electronic device coupled thereto;

FIG. 4C is a block diagram of another embodiment of a vehicle electronic system with an embodiment of a portable electronic device coupled thereto;

FIG. 5 is an illustration of another embodiment of a docking assembly for a portable electronic device, the embodiment including a detachable adapter unit;

FIG. 6 is a front view of one embodiment of a portable electronic device coupled to a docking assembly via a detachable adapter;

FIG. 7 is a perspective view of one embodiment of a portable electronic device coupled to a docking assembly;

FIG. 8 is a perspective view of one embodiment of a docking assembly including a detachable adapter coupled to a double DIN unit;

FIG. 9 is a perspective view of one embodiment of a portable electronic device coupled to a docking assembly in double DIN unit via a detachable adapter;

FIG. 10A is a drawing illustrating one embodiment of a docking assembly having electro-mechanical connectors for securing a portable electronic device;

FIG. 10B is a drawing illustrating one embodiment of a docking assembly having an ejection mechanism;

FIG. 11 is an overhead view of one embodiment of an automobile interior having multiple docking assemblies;

FIG. 12 is a perspective view of one embodiment of a portable electronic device coupled to a docking assembly in an automobile dashboard;

FIG. 13 is a front view of one embodiment of a portable electronic device coupled to a docking assembly in an automobile dashboard; and

FIG. 14 is a perspective view of different vehicle types that may include an embodiment of a docking assembly.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling within the spirit and scope of the present invention as defined by the appended claims.

### DETAILED DESCRIPTION

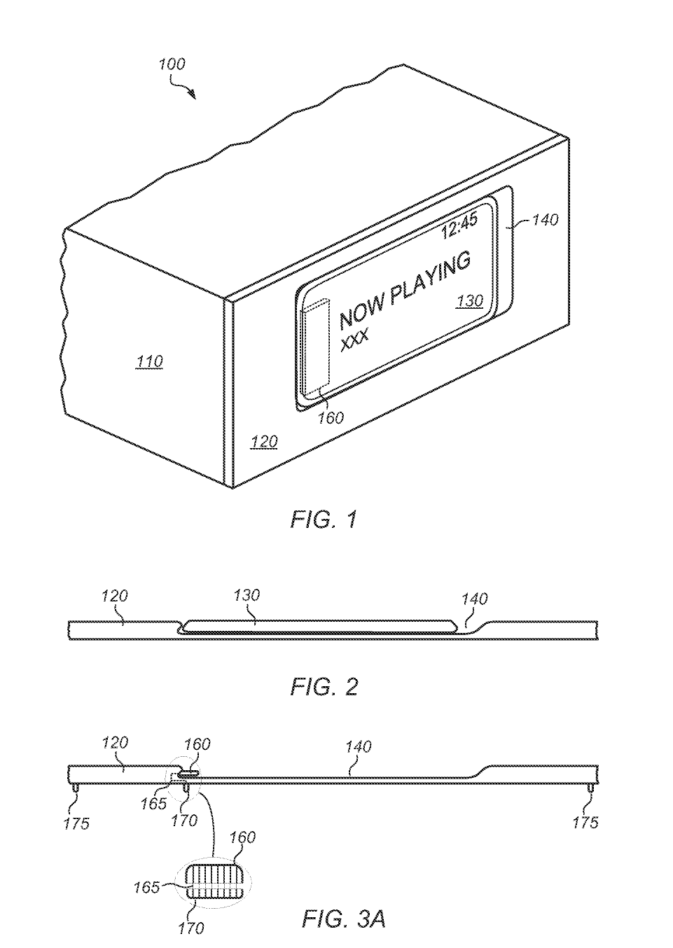

FIG. 1 is an illustration of one embodiment of a portable electronic device coupled to a docking assembly. In the embodiment shown, assembly 100 includes portable electronic device (PED) 130 is mechanically coupled to DIN unit 110. More particularly, PED 130 may be coupled to DIN unit 110 via a faceplate 120. When coupled together, faceplate 120 and DIN unit 110 form a housing unit in which at least a first portion of a vehicle electronic system is contained. In this particular example, faceplate 120 includes a recess 140 that may form a docking port configured for receiving PED 130. Recess 140 in the embodiment shown is configured to accommodate PED 130. Recess 140 may have a form factor conforming to the size and shape of a particular PED 130. A connector 160 (shown by dashed lines) may be located under PED 130, and may be integrated into faceplate 120. In the embodiment shown, connector 160 may be configured for electrically coupling PED 130 to the vehicle electronic system (to be discussed below) that is at least partially contained within DIN unit 110. Furthermore, faceplate 120 may be configured to be easily removable and replaceable with another embodiment of faceplate 120 having another type of docking recess 140 that conforms to the size and shape of another type of PED 130. Accordingly, assembly 100 may be adaptable to a wide variety of different types of PED's 130 through the use of corresponding embodiments of faceplate 120.

In the example shown, connector 160 is shown here as dashed lines to indicate that it is behind faceplate 120. As noted above, connector 160 is configured to electrically couple PED 130 to a vehicle electronic system that is at least partly contained within DIN unit 110. Connector 160 may be a male or female connector, with a complementary connector being present on either an adapter unit or on PED 130 itself. In one embodiment, connector 160 may be a 30-pin male, parallel connector used with a corresponding female connector certain types of ‘smart’ phones and portable media players (e.g., the male connector used to connect to the Apple iPhone™ and certain models of the iPod™). However, many different types of connectors are possible, and such connectors may be parallel connectors or serial connectors. An intervening connector may be included on faceplate 120 that provides the electrical connection between PED 130 and connector when faceplate 120 is attached to DIN UNIT 110. Through the intervening connector (examples of which will be discussed below) and connector 160, PED 130 may exchange signals with the vehicle electronic system. Such a signal exchange may include the provision of audio signals to the vehicle electronic system, in either digital or analog format. The signal exchange may be conducted through hardwired connections, and thus may obviate the need for the transmission of wireless signals. In some embodiments, signals may be conveyed through connector 160 that enable PED 130 to control the vehicle electronic system or utilize its various output mechanisms. Additional details of an interface between PED 130 and a vehicle electronic system will be discussed in further detail below.

Although not explicitly shown here, faceplate 120 and/or DIN unit 110 may also include one or more mechanical connectors configured to secure faceplate 120 into position when attached to DIN unit 110. Such connectors may include traditional types of fasteners (e.g., screws, thumbscrews, etc.) or any other type of connecting apparatus that may secure faceplate 120 to DIN unit 110.

Turning now to FIG. 2, a view of one embodiment of a docking port having a PED 130 inserted therein is shown. In the embodiment shown, PED 130 is mounted to faceplate 120 and within docking recess 140. In some embodiments, PED 130 may be first coupled to faceplate 120 before finally coupling faceplate 120 to a DIN unit 110. In other embodiments, faceplate 120 may remain coupled to DIN unit 110 regardless of whether or not PED 130 is coupled thereto

In this particular example, PED 130 is nearly (although not completely) flush with the upper (or outer) surface of faceplate 120. Embodiments are possible and contemplated wherein a particular PED 130 may be flush with the upper surface of faceplate 120, may extend beyond the upper surface of faceplate 120. Embodiments are also possible and contemplated wherein PED 130 does not extend all the way to the upper surface of faceplate 120. In general, a wide variety of embodiments of faceplate 120 that correspond to embodiments of PED 130 of varying shapes and sizes are possible and contemplated.

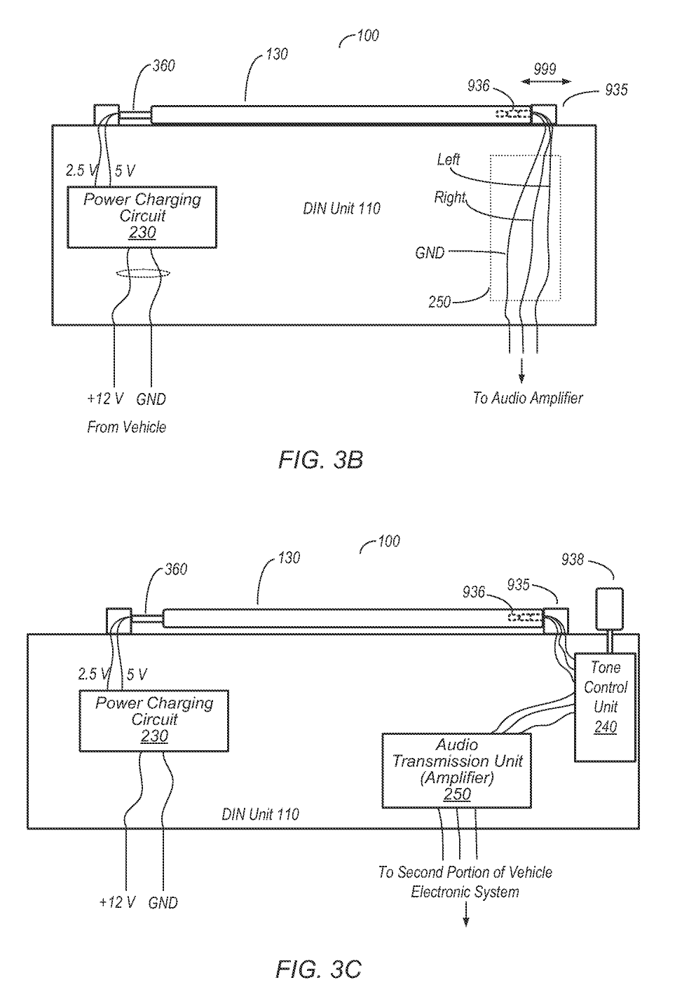

FIG. 3A is a view of the same embodiment of faceplate 120 shown in FIG. 2, without PED 130 inserted therein and showing additional details regarding the mechanical and electrical connections. In the embodiment shown, faceplate 120 includes an electro-mechanical connector 160 that is configured to be coupled to a corresponding connection of PED 130. In addition to providing a mechanical connection to a PED 130, connector 160 may also provide electrical connections to enable the exchange of signals between PED 130 and a vehicle electronic system when coupled thereto. Faceplate 120 in the embodiment shown also includes a second electro-mechanical connector 170 extending from the bottom thereof (as shown in the drawing). Connector 170 in the embodiment shown is a male connector configured to plug into a corresponding female connector of DIN unit 110 discussed above. It is noted however that embodiments wherein connector 170 is a female connector while DIN unit 110 includes a male connector are also possible and contemplated.

Faceplate 120 may also include one or more mechanical connectors 175 (two are shown in this particular example). The mechanical connectors 175 may be used to mechanically secure faceplate 120 to DIN unit 110. Such connectors 175 may, in some embodiments, include additional elements, such as a thumbscrew or other type fastener that may further secure faceplate 120 into place. In other embodiments, no extra fasteners or other elements are included. It is further noted that DIN unit 110 may include corresponding portions that enable mechanical connectors 175 to couple faceplate 120 thereto.

Signal connections of connector 160 may each be coupled to corresponding signal connection of connector 170 via one or more signal lines 165. FIG. A3 includes an additional view of one embodiment of the interface between connectors 160 and 170 via signal lines 165. It is noted that this embodiment is but one possible embodiment, and numerous types of connectors 160 and 170 are possible and contemplated. Connector 160 may conform to a particular type of PED 130 that may be coupled to the vehicle electronic system via faceplate 120. Some connector types that are possible and contemplated for connector 160 include (but are not limited to) Universal Serial Bus (USB) connectors, micro USB connectors, Firewire connectors, various types of proprietary connectors that may be arranged for use with a particular type of PED 130, and so forth. In general, for a given embodiment of faceplate 120, connector 160 may be any type of connector that is suitable for coupling (both electrically and mechanically) to a particular PED 130. Since there are a large number of manufacturers that provide many different types of portable electronic devices in today's market (with many new devices to be introduced in the future), it follows that the particular form of connector 160 may vary widely from one embodiment to the next.

Connector 170 may be configured according to the corresponding connector in DIN unit 110. The physical configuration of connector 170 does not necessarily need to physically conform to the PED 130, but instead may conform to a corresponding connector (male or female) of DIN unit 110. Accordingly, embodiments of connector 170 may vary in accordance with the corresponding connector provided in DIN unit 110. These connectors may be standardized for a variety of embodiments of faceplate 120, thereby allowing a number of different embodiments of a PED 130 to be coupled to a vehicle electronic system that includes one or more components within DIN unit 110.

FIG. 3B is a top view of one embodiment of a docking assembly 100 with an embodiment of PED 130 coupled thereto. In this example, PED 130 is coupled to docking assembly 100 such that its back surface is substantially in contact with the front surface of DIN unit 110. However, embodiments wherein space is provided between PED 130 and a housing such as DIN unit 110 are also possible and contemplated, and will be discussed below.

In the embodiment shown, connectors 360 and 935 perform the dual function of both electrically coupling PED 130 to a first portion of a vehicle electronic system, as well as mechanically coupling PED 130 to DIN unit 110. Connector 360 in this embodiment is a multi-pin connector (e.g., such as the 30 pin connector discussed above). Connector 935 in this embodiment is a headphone jack connector, and thus includes pin 936 (shown here in dashed lines), which is suitable for insertion into a corresponding headphone jack of PED 130. As indicated by arrows 999, connector 935 may slide in two different directions as viewed in this example: to the left (for insertion of pin 936 into the corresponding headphone jack of PED 130, or to the right for removal of pin 936.

Thus, for the embodiment shown, PED 130 may be mechanically coupled to PED 130 by connecting it to connector 360 and subsequently sliding connector 935 into position to fully insert pin 936 into the corresponding headphone jack. The act of mechanically coupling and securing PED 130 to housing unit 110 in this embodiment also results in the electrical coupling of PED 130 to a first portion of a vehicle electronic system housed within DIN unit 110. Removal of PED 130 may be accomplished in this embodiment by sliding connector 935 far enough in the rightward direction to fully remove pin 936 from the headphone jack of PED 130 and subsequently disconnecting PED 130 from connector 360.

In this particular embodiment, the first portion of the vehicle electronic system includes power charging circuit 230 and audio transmission unit 250. Power charging circuit 230 in the example shown is coupled to +12 volt and ground ('GND') wires of a second portion of a vehicle electronic system. Power charging circuit 230 thus receives power from the second portion of the vehicle electronic system in this embodiment. Power charging circuit 230 may include one or more voltage regulating circuits therein, and is coupled by the indicated wires to provide 2.5V and 5V power to PED 130. The 2.5V and 5V power may be provided to a battery within PED 130, which may be charged when coupled to connector 360.

Audio transmission unit 250 in this embodiment includes wires coupled to convey audio signals for a left speaker, a right speaker, and also includes a ground wire. These wires may convey audio signals transmitted from PED 130 through pin 936 to an audio amplifier in the second portion of the vehicle electronic system. It is noted however that more complex audio transmission units 250 than that shown in FIG. 3B are possible and contemplated, as will be discussed in further detail below.

FIG. 3C is a top view of another embodiment of a docking assembly 100 with PED 130 coupled thereto. Docking assembly 100 of FIG. 3C utilizes the same type of connectors as used for the embodiment shown in FIG. 3B, and may be connected and disconnected in the same manner. However, in the embodiment of FIG. 3C, PED 130 is not mounted in such a way that its back surface is in contact with the front portion of DIN unit 110. This configuration may be useful if it is desirable to allow airflow between PED 130 and DIN unit 110 for cooling purposes.

In the embodiment shown in FIG. 3C, the first portion of the vehicle electronic system (i.e. the portion housed within DIN unit 110) includes power charging circuit 230, which is similar to that of FIG. 3B. The first portion of the vehicle electronic system in this embodiment also includes tone control unit 240 and audio transmission unit 250, which in turn comprises an amplifier in this embodiment. Tone control unit 240 may receive the audio signals from PED 130 (via pin 936), and may be configured to alter one or more characteristics of the audio signals. For example, tone control unit 240 may be configured to adjust the bass, the treble, or the balance characteristics of the audio signals received from PED 130. Some more advanced embodiments of tone control unit 240 may provide a graphic equalizer function. In this particular embodiment, ton control circuit 240 may be controlled by one or more knobs 938 (only one of which is shown here for the sake of simplicity). The knobs 938, located on the front of docking assembly 100, may be manually turned by an operator to adjust the audio signal characteristics. The audio signals that have had their characteristics adjusted by tone control unit 240 may be received by the amplifier comprised in audio transmission unit 250. The amplifier in audio transmission unit 250 may amplify the audio signals and then transmit them to a second portion of the vehicle electronic system, various embodiments of which will now be discussed in further detail.

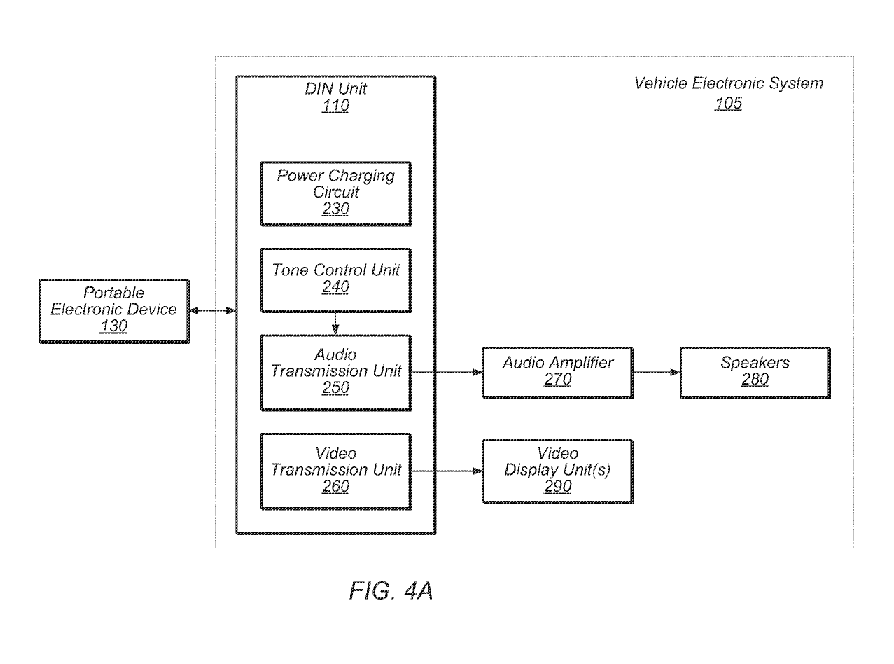

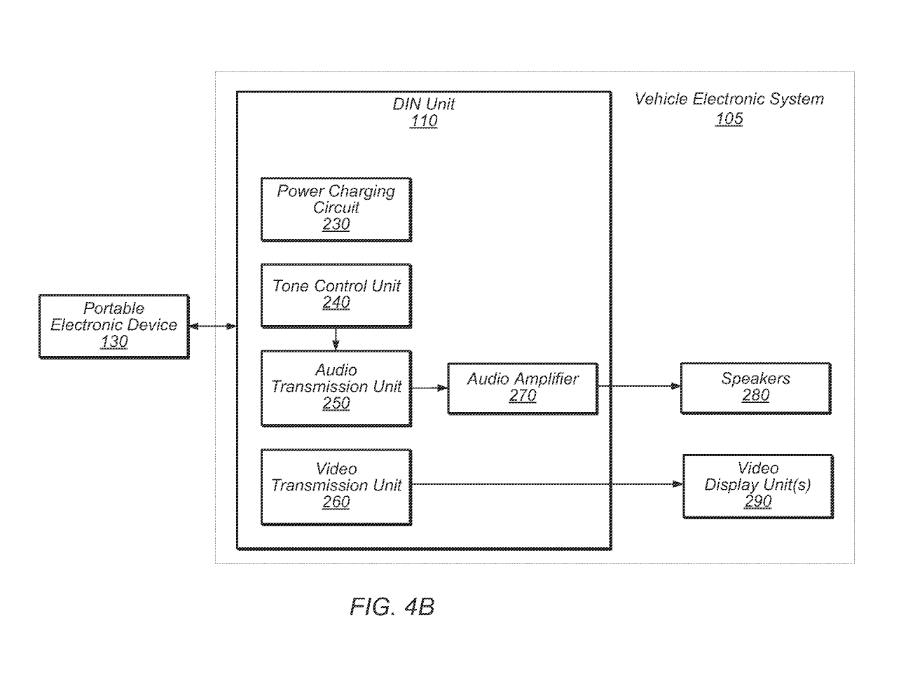

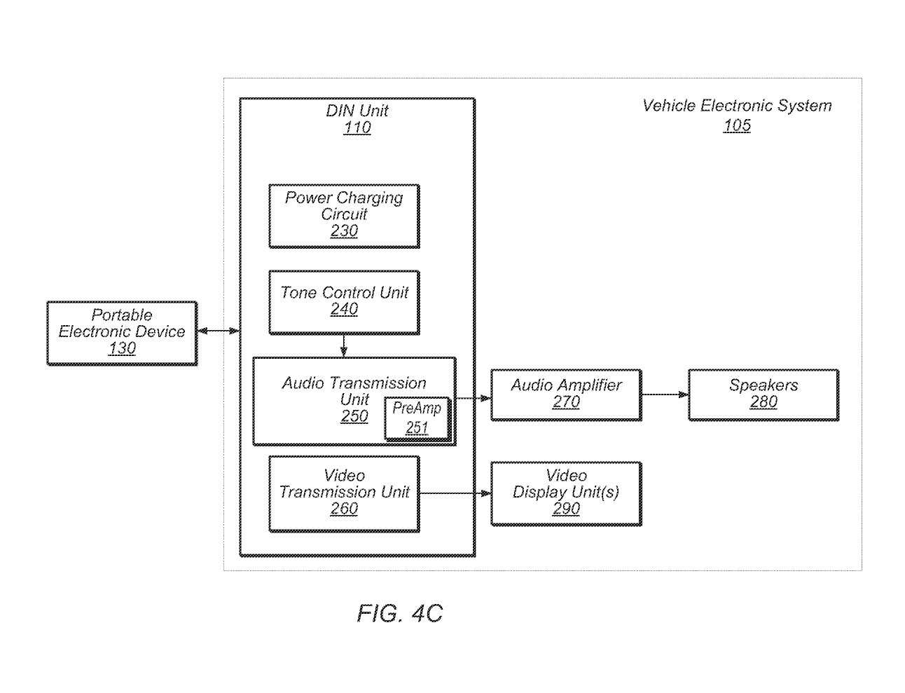

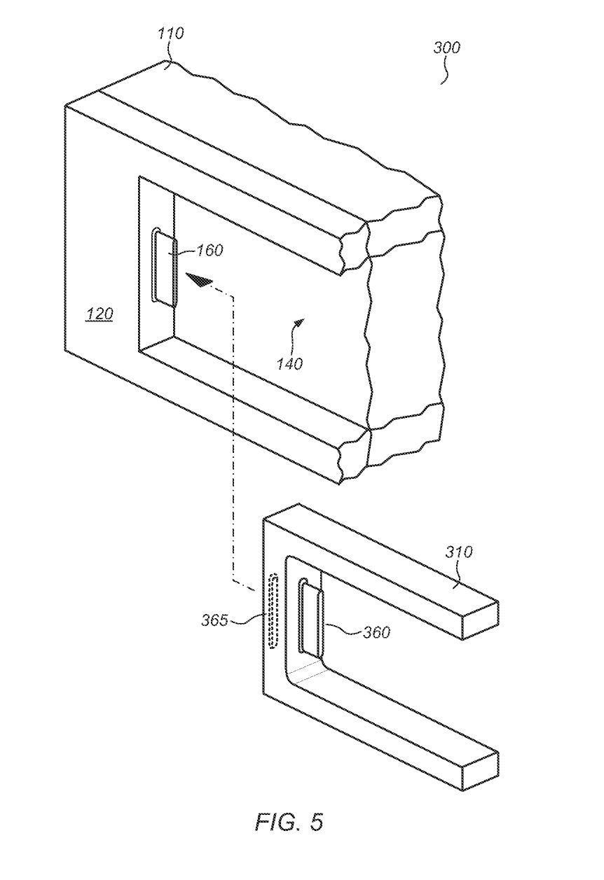

FIG. 4A is a block diagram of one embodiment of a vehicle electronic system with an embodiment of a portable electronic device coupled thereto. In the embodiment shown, PED 130 is coupled to vehicle electronic system 105, which may be implemented within an automobile, a boat, or any other type of vehicle. Vehicle electronic system 105 may be coupled to receive power from a vehicle electrical system (not shown), which may include a battery (e.g., a car battery) as well as an alternator or other means for generating power when the vehicle is operating.

Vehicle electronic system 105 may include a DIN unit 110 to provide housing for one or more functional units. In this particular example, DIN unit 110 provides housing for a power charging circuit 230, a tone control unit 240, an audio transmission unit 250, and a video transmission unit 260. In some embodiments, one or more of these units may be located external to DIN unit 110 (e.g., elsewhere behind the dashboard of an automobile). Furthermore, embodiments of vehicle electronic system that include additional units housed within DIN unit 110 are also possible and contemplated. Embodiments are also possible and contemplated wherein housing alternate to DIN unit 110 is used.

Vehicle electronic system 105 further includes an audio amplifier 270 in the embodiment shown. Audio amplifier 270 may receive audio signals conveyed and/or transmitted from audio transmission unit 250 and amplify these signals. In some embodiments, an amplifier (sometimes referred to as a pre-amplifier) may be included as part of audio transmission unit 250. Accordingly, the task of amplifying may be divided between the amplifier in audio transmission unit 250 and audio amplifier 270 in such embodiments. The amplified audio signals provided by audio amplifier 270 may be provided to speakers 280. In other embodiments, audio transmission unit 250 may be as simple as a group of wires that convey audio signals received from PED 130 to audio amplifier 270.

Vehicle electronic system 105 may include one or more speakers in various embodiments, and the particular number of speakers is limited only by the particular arrangement of the vehicle in which vehicle electronic system 105 is implemented. Furthermore, the number and type of speakers 280 for a particular vehicle electronic system 105 may change due to aftermarket modifications.

When coupled to vehicle electronic system 105, PED 130 may exchange signals with the various units therein and may also control at least some aspects of their operation. For example, PED 130 may provide audio signals to audio transmission unit 250. These audio signals may then be amplified by audio amplifier 270 and output by speaker 280. The volume of these audio signals may be controlled by PED 130, which may send signals to audio transmission unit 250 indicating the requested volume level. Audio transmission unit 250 may respond to volume control signals received from PED 130 by adjusting the amplitude of audio signals provided to audio amplifier 270.

In some embodiments, the audio signals provided by PED 130 may be in analog form when received by audio transmission unit 250. In other embodiments, PED 130 may transmit digital signals to audio transmission unit 250. The digital signals may then be converted by audio transmission unit 250 into analog format before being transmitted to audio amplifier 270. In one embodiment, PED 130 may play back a digital music file (e.g., in .mp3 format) by transmitting the file digitally to audio transmission unit 250 wherein a subsequent analog conversion takes place before transmission of signals to the audio amplifier. In general, audio transmission unit 250 may vary from one embodiment to the next. In some embodiments, audio transmission unit 250 may be as simple as the wire embodiment shown in FIG. 3B. In other embodiments, audio transmission unit 250 may include circuitry for digital-to-analog conversion of digital video files received from PED 130, amplification circuitry, and any other type of audio processing circuitry that can be used to affect the characteristics of the sound that is eventually output by speakers 280.

Tone control unit 240 may also be included in various embodiments of vehicle electronic system 105, and may be used to adjust certain characteristics of the audio signals. For example, tone control unit 240 may be configured to adjust the bass or treble of audio signals. In some embodiments, tone control unit 240 may implement a graphic equalizer function. PED 130 may provide control signals for performing adjustments to the audio signals in tone control unit 240 in some embodiments. In other embodiments, separate controls may be provided for tone control unit 240. Tone control unit 240 is shown here as an entity separate from audio transmission unit 250. However, embodiments are also possible and contemplated wherein tone control unit 240 is incorporated within audio transmission unit 250.

In the embodiment shown, vehicle electronic system 105 includes a video display unit 290, which is coupled to receive video signals from video transmission unit 260. Some embodiments of vehicle electronic system 105 may include multiple video display units 290, and embodiments that include no video display units are also possible and contemplated. Each video display unit 290 in a given embodiment may play video in accordance with the signals transmitted thereto from video transmission unit 290. Some embodiments that include multiple instances of video display unit 290 may display different video outputs on one or more of the multiple instances. For example, on one video display unit, a user may watch a movie, while on another video display unit, a user may view navigation information.

Video transmission unit 260 in the embodiment shown may be configured to receive multiple types of video signals from a PED 130. For example, embodiments are possible and contemplated wherein a PED 130 may provide one or more of the following types of video signals to video transmission unit 260: composite video signals, component video signals, S-video signals, and digital video signals. Some embodiments of a PED 130 may provide one or more of these types of video signals, while some embodiments may be configured to provide all of these types of video signals. Similarly, video transmission unit 260 may be configured to receive and process one or more of these video signal types, and in some cases, all of these types. Processing of the video signals may include adjustments to brightness, contrast, color, and so forth, and may also include the conversion of digital video signals into an analog format, as well as the general conversion of signals into a format suitable for playback on video display unit 290, if necessary.

Many embodiments of PED 130 may include a battery used to power operation when the PED is otherwise not coupled to another source of power. Since battery life is limited, the batteries of these embodiments of PED 130 will require recharging after a certain amount of use. Accordingly, vehicle electronic system 105 may include a power charging circuit 230, which may be used to charge the batteries of PED 130 when the latter is coupled to the former. Thus, PED 130 may operate on power supplied by vehicle electronic system 105 when coupled thereto while also recharging its batteries for subsequent operation independent of vehicle electronic system 105.

PED 130 may come in a wide variety of embodiments. Various embodiments of PED 130 include (but are not limited to) a cellular phone, a portable music player configured to play digital audio files, a portable Internet access device, a personal digital assistant (PDA), a global positioning system (GPS) navigation device, a portable multimedia device capable of playing both audio and video files, and so forth. Embodiments of PED 130 that incorporate multiple functions including two or more of those discussed above are also possible and contemplated. For example, one embodiment of PED 130 includes the functions of a cellular phone, a portable multimedia player, a GPS navigation device, and Internet access device (including e-mail capabilities). These functions may be accessed by a user through a touch screen in some embodiments, through various keys and buttons in other embodiments, or through a combination of keys/buttons and touch screen operations.

Various embodiments of PED 130 may be used to replace certain functions provided by previous vehicle electronic systems. For example, an embodiment of PED 130 having digital music playback capability may be used to replace functions of an in-vehicle compact disk (CD) or cassette tape player. In another example, a PED 130 having video playback capabilities may be used to replace at least a portion of a stand-alone video playback system in a vehicle, although such an embodiment may nevertheless utilize video display unit 290. However, the need for digital video disks (DVD's) as a carrier medium for storing the video information may be eliminated. In yet another example, PED 130 may be able to replace the functionality of a stand-alone GPS navigation system in a vehicle. A PED 130 configured for mobile, wireless internet access may access internet-based radio to replace the radio function in a vehicle. Various embodiments of a PED 130 are also possible and contemplated wherein a standard radio (e.g., AM and/or FM radio) is included therein, thereby including a capability to provide those functions in addition to or as an alternative to Internet radio. In some embodiments, PED 130 may be configured to receive satellite radio signals, and may replace a standard satellite radio receiver. FMHD (frequency modulation high definition) another radio format for which some embodiments of PED 130 may be capable of reception and the playing of audio based on the received signals.

A cellular telephone function provided in a PED 130 may also utilize portions of vehicle electronic system. For example, an embodiment of PED 130 is possible and contemplated wherein received audio from a telephone call may be played back on the speakers of vehicle electronic system 105. Audio signals originating from incoming signals during a phone call may be transmitted to audio transmission unit 250, and thus to audio amplifier 270 and then to speakers 280. Utilizing the speakers 280 of vehicle electronic system 105 during utilization of a cellular telephone function of PED 130 may thus allow a higher quality voice audio to be heard than may otherwise be possible when conversing in a moving vehicle while being unable to hold PED 130 close enough to an operator to adequately hear the audio. The speakers 280 may also be used to output audio when answering voice mails or listening to voice memos from PED 130.

An operator or passenger in a vehicle having a cellular telephone configured PED 130 coupled to vehicle electronic system 105 by a docking system may be able to take incoming calls in a largely hands-free manner. When an incoming call is indicated on PED 130, when coupled to vehicle electronic system 105, a person within the vehicle may press a key or a key/button or a portion of a touch screen in order to pick up the call, and may do the same to end the call at its conclusion. In the time between picking up and ending a call, the operator may converse with the other caller without touching PED 130 and while listening to the audio contained in incoming signals through the speakers of vehicle electronic system 105. A similar process may take place when initiating a call, although additional keystrokes may be required to dial a phone number of an intended recipient. However, some embodiments of PED 130 may be able to operate by voice-activated commands. Accordingly, it is contemplated for some embodiments of PED 130 that an operator may be able to initiate a call, converse during the call, and terminate the call without having to actually touch PED 130.

FIG. 4B a block diagram of another embodiment of a vehicle electronic system with an embodiment of PED 130 coupled thereto. In this particular embodiment, audio amplifier 270 is housed within DIN unit 110. In general, embodiments are possible and contemplated wherein a majority of the functional units of vehicle electronic system 105 are housed within DIN unit 110. Certain functional elements such as speakers 280, video display units 290, and other portions of vehicle electronic system 105 not suitable for housing within DIN unit 110 may be located elsewhere as part of the second portion of the vehicle electronic system. However, embodiments similar to FIG. 4 may house in DIN unit 110 any functional unit that is suitable for the same.

A block diagram of yet another embodiment of vehicle electronic system 105 having PED 130 coupled thereto is shown in FIG. 4C. In this particular embodiment, audio transmission unit 250 includes an amplifier (‘PreAmp’) 251. Thus, the amplification of audio signals may be a two-stage process in this embodiment, with amplifier 251 providing the first stage in audio transmission unit 250, and audio amplifier 270 providing the second stage. Other functionality may also be implemented within audio transmission unit 250. Furthermore, in embodiments where amplifier 251 provide sufficient power, audio amplifier 270 may be eliminated, with amplifier 251 being connected directly to speakers 280.

FIG. 5 is an illustration of another embodiment of a docking assembly for a portable electronic device, the embodiment including a detachable adapter unit. In the embodiment shown, docking assembly 300 includes a faceplate 120 coupled to a DIN unit 110. Faceplate 120 also includes a recess 140 in this embodiment, which may enable faceplate 120 to accommodate adapter 310 and a PED 130 (not shown in this drawing).

Adapter 310 in the embodiment shown includes a connector 360. The connector 360 may be arranged to electrically and mechanically couple adapter 310 to a PED 130. After coupling PED 130 to adapter 310, adapter 310 may be electrically and mechanically coupled to faceplate 120 by inserting it into recess 140. Adapter 310 may also include a female connector 365, which is configured to be coupled to connector 160 of faceplate 120. In the embodiment shown, connector 160 is a male connector, however it is noted that embodiments are possible and contemplated wherein the arrangement is reversed, i.e. where connector 365 is a male connector and connector 160 is a female connector.

When connectors 365 and 160 are coupled together in the embodiment shown, and a PED 130 is coupled to adapter 310 via connector 360, the PED 130 may be electrically coupled to a vehicle electronic system that includes at least one component contained with in DIN unit 110.

Adapter 310 may come in a wide variety of embodiments, with a given embodiment being configured for receiving a particular type of PED 130. Furthermore, connector 360 of adapter 310 may also be configured to couple to a particular type of PED 130. Connector 160 of faceplate 120 and the complementary connector 360 of adapter unit 310 may be standardized connectors, and thus any of a wide variety of embodiments of adapter 310 may be coupled to faceplate 120. With respect to the physical shape of adapter 310, the exterior portion of various embodiments thereof may be standardized in such a manner to fit in faceplate 120. However, the interior portion of adapter 310, along with connector 360, may be adapted to a particular type of PED 130. This may enable docking assembly 300 to have the flexibility to accommodate a wide variety of different embodiments of PED 130. This may in turn enable a user to change from one type of PED 130 to another without requiring replacement of the entire docking assembly.

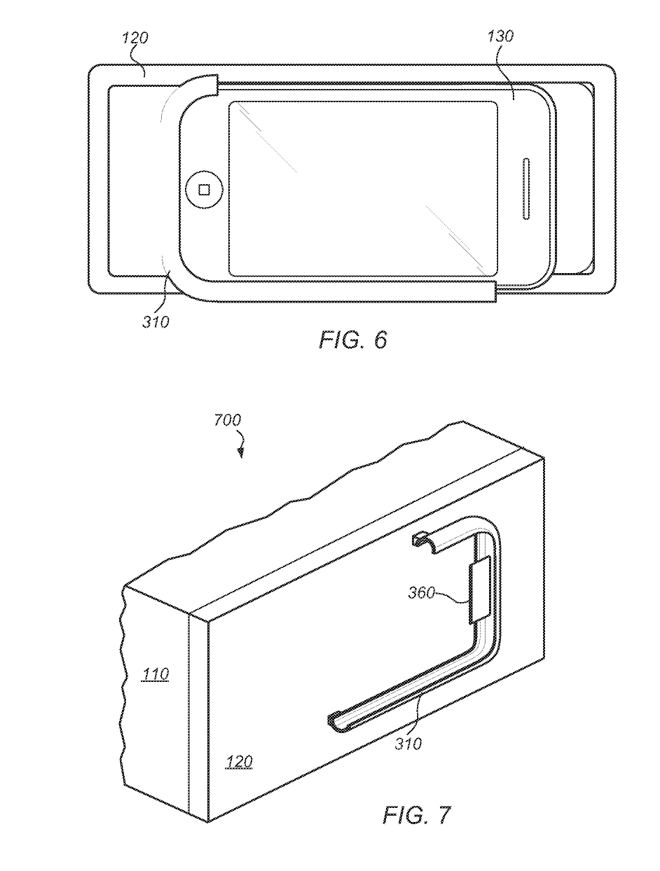

FIG. 6 is a front view of one embodiment of a portable electronic device coupled to a docking assembly via a detachable adapter. In this example, PED 130 is coupled to adapter 310, which in turn is coupled to faceplate 120. Although not explicitly shown herein, PED 130 may be coupled to a connector of adapter 310 while adapter 310 is coupled to faceplate 120 by a connector arrangement similar to that shown in FIG. 5. Faceplate 120 may also be coupled to a DIN unit 110 or other housing containing one or more units of a vehicle electronic system 105. Thus, when coupled as shown, PED 130 may be electrically coupled to a vehicle electronic system 105, and may thus be able to exchange signals and perform various functions as described above with reference to FIG. 4.

FIG. 7 is a perspective view of one embodiment of a docking assembly including a detachable adapter 310 coupled to a double DIN unit. In this embodiment, docking assembly 700 includes an adapter unit 310 coupled to a faceplate 120. Faceplate 120 in this particular embodiment does not include a recess (e.g., such as recess 140 of FIG. 5). Although not explicitly shown here, faceplate 120 and adapter 310 may be coupled by a connector arrangement similar to that shown in FIG. 3 as coupling that particular embodiment of faceplate 120 to DIN unit 110.

In the embodiment shown, adapter unit 310 includes one long member towards its bottom and another shorter member towards its top (as shown in the drawing). The members may have a concave shape that is designed to mechanically secure a PED 130 when coupled to connector 360 (which is configured to provide both a mechanical and electrical connection to a vehicle electronic system through corresponding connectors arranged in a manner in accordance with one of the other embodiments discussed above. A PED 130 may be secured in place by coupling its corresponding female connector to the male connector 360 in this embodiment, while the members of adapter unit 310 provide further support to hold PED 130 in place. It is noted that in some embodiments, connector 360 may be a female connector, while a corresponding PED 130 may include a complementary male connector.

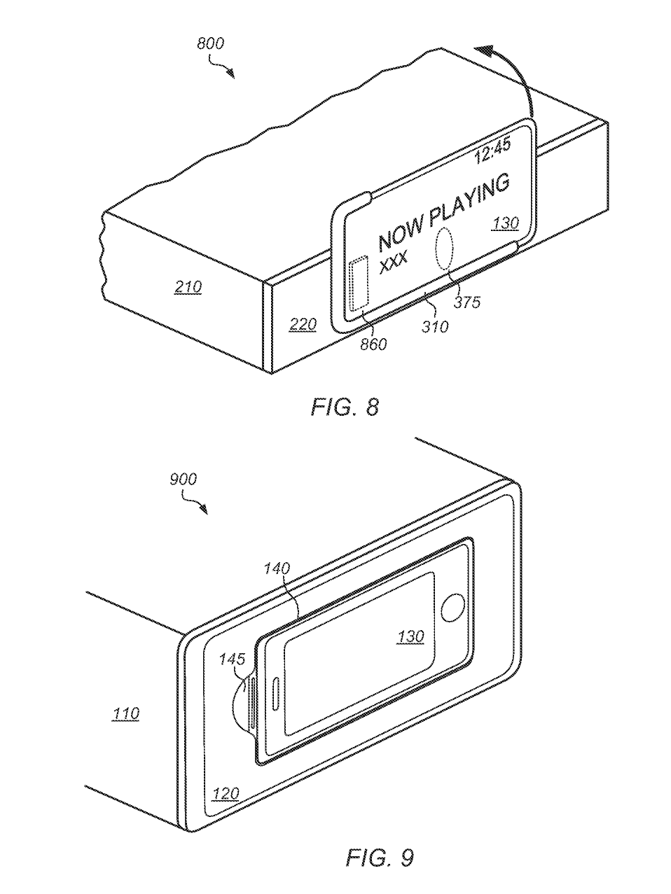

FIG. 8 is a perspective view of one embodiment of a portable electronic device coupled to a docking assembly in a single DIN unit via a detachable adapter. In this particular embodiment, assembly 800 includes a single DIN unit 210 having a correspondingly sized faceplate 220 coupled thereto. Adapter unit 310 may be configured to accommodate PED 130 and to be coupled to faceplate 220. In this particular embodiment, a connector arrangement 860 may be located underneath PED 130 (when inserted), thereby providing electrical coupling to a vehicle electronic system 105.

The connector arrangement 860 in this particular embodiment may include one or more wires or one or more ribbon cables that allow for some flexibility of movement. This may in turn allow for PED 130 and adapter unit 310 to be rotated, as suggested by the arrow in the drawing. Adapter unit 310 may also include a mechanical coupling member 375 (shown here in a dashed oval) on its underside. This member may enable coupling of adapter unit 310 to faceplate 220 and may also enable the rotation of PED 130 while inserted into adapter unit 310. This in turn may enable an operator of PED 130 to view the display in a landscape mode (when arranged as shown) or in a portrait mode (when turned counter clockwise by approximately 90 degrees). When not in use, adapter 310 may be detached from faceplate 220.

FIG. 9 is a perspective view of embodiment of a portable electronic device coupled to another embodiment of a docking assembly. In this particular example of assembly 900, faceplate 120 may act as an adapter unit for coupling PED 130 to a vehicle electronic system 105 that is at least partially contained within double DIN unit 110. Although not explicitly shown here, faceplate 120 may include an arrangement of connectors in accordance with one of the embodiments discussed above to enable electrical coupling between PED 130 and the vehicle electronic system 105.

As shown in this example, PED 130 is accommodated by recess 140 of faceplate 120. Faceplate 120 also includes an additional recess 145 in this embodiment. Recess 145 may be relatively small in comparison to recess 140, but may nevertheless provide enough space for a user to grip a portion of PED 130 for removal from faceplate 120. Recess 145 may also provide sufficient space for a user to push PED 130 into place when inserting it into assembly 900.

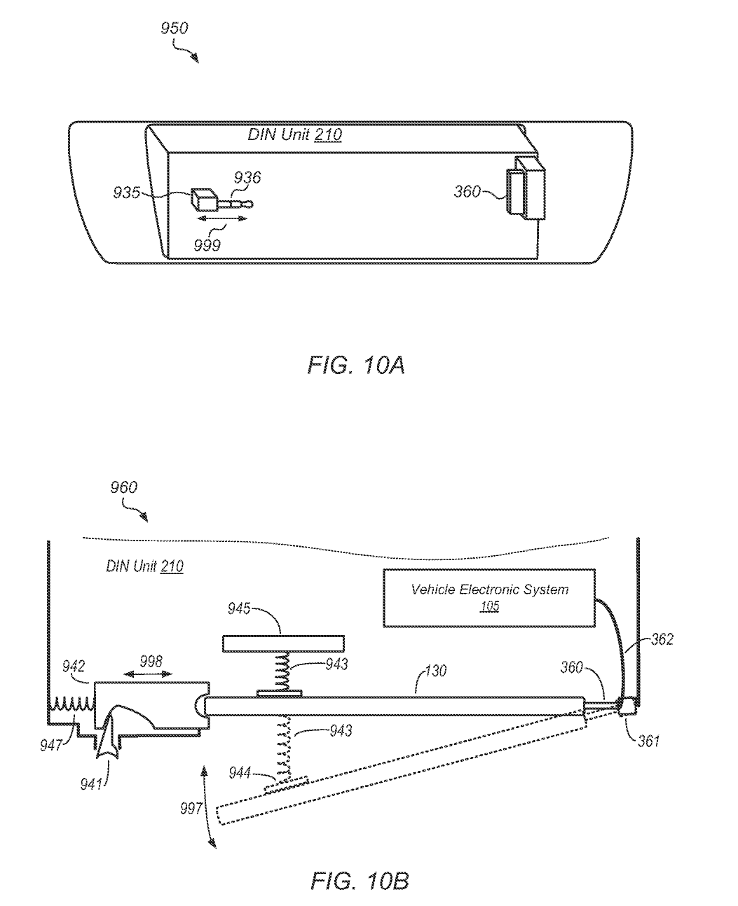

Turning now to FIG. 10A, a drawing illustrating one embodiment of a docking assembly having electro-mechanical connectors for securing a portable electronic device is shown. The embodiment shown of docking assembly 950 shown in FIG. 10A is similar to those shown in FIGS. 3B and 3C, including a connector 360 and a connector 935 including pin 936 for insertion into a headphone jack of a PED 130. In this particular embodiment, DIN unit 210 is a single DIN unit, although embodiments similar to the one shown here utilizing a double DIN unit or a 1.5 DIN unit are also possible and contemplated. As noted in the discussion of the embodiments of FIGS. 3B and 3C, connector 936 may be slidable in either direction as indicated by arrows 999. Accordingly, a PED 130 may be mechanically coupled to DIN unit 210 by connecting it to connector 360 and subsequently sliding connector 935 toward the right until pin 936 is fully inserted into a corresponding headphone jack. This mechanically secures PED 130 to DIN unit 210, and may also electrically couple it to a first portion of a vehicle electronic system.

Decoupling of PED 130 from DIN unit 210 may be accomplished by sliding connector 935 to the left until pin 936 is fully removed from the headphone jack. Afterward, PED 130 may be disconnected from connector 360. The mechanical (and electrical) decoupling of PED 130 from DIN unit 210 in this particular embodiment does not require an ejection mechanism, and thus removal/insertion of the PED 130 may be accomplished by user force. Another embodiment of a docking assembly that utilizes an ejection mechanism will now be discussed in further detail.

FIG. 10B is a drawing illustrating one embodiment of a docking assembly having an ejection mechanism. In the embodiment shown, docking assembly 960 may utilize an ejection mechanism for removal of PED 130. Various components of the ejection mechanism may also secure PED 130 to DIN unit 210 when inserted.

In this particular embodiment, the ejection mechanism includes button 941, sliding element 942, spring 947 (coupled to sliding element 942), stabilizing element 945, spring 943 (coupled to stabilizing element 945), and pushing element 944. Removal of a PED 130 that is inserted into docking assembly 960 may commence with the pushing of button 941 by a user. The pushing of button 941 inward (i.e. in the direction indicated by the upward arrow of 997) may cause sliding element 942 to move to the left, as indicated by the left hand arrow of 998. When sliding element 942 has moved sufficiently to the left, pushing element 944 is pushed outward in the direction of the downward arrow due to the force of spring 943. This in turn may cause PED 130 to be pushed outward, as indicated by the portions of PED 130, spring 942, and pushing element 944 shown in dashed lines. At this point, connector 360 may be still connected to PED 130. In the embodiment shown, connector 360 is coupled to a swivel element 361, which may swivel outward with PED 130 in order to allow for the required flexibility for insertion and removal of PED 130. After PED 130 has been released by sliding element 942 and pushed outward, it may be manually decoupled from connector 360, thereby decoupling it from DIN unit 210.

To couple PED 130 to DIN unit 210, PED 130 may first be connected to connector 360. After this connection is made, button 941 may be pushed inward (upward arrow of 997), with PED 130 also being pushed inward. Once PED 130 is in position, as shown in solid lines, button 941 may be released. When button 941 is released, spring 947 may cause sliding element to move in the direction indicated by the rightward arrow of 998. Sliding element 942 includes a concave portion as shown in the drawing that may receive a portion of PED 130 therein, thus retaining it in position. At this point, PED 130 is mechanically coupled to DIN unit 210 and electrically coupled to vehicle electronic system 105.

In the embodiment shown, connector 360 is coupled to a ribbon cable 362, which provides an electrical connection to vehicle electronic system 105. Ribbon cable 362 may provide enough flexibility to allow for swivel element to rotate on its axis for coupling and decoupling of PED 130 and connector 360. Although not explicitly shown here, a pin suitable for insertion into a headphone jack (e.g., such as pin 936 shown in FIG. 10A) may be located on sliding element 960. Thus, in such embodiments a second electrical connection may be provided, as is provided in the embodiment of FIG. 10A. However, embodiments that do no require such a connection are also possible and contemplated.

The ejection mechanism shown herein is but one of a number of possible embodiments of such an ejection mechanism. A particular embodiment of an ejection mechanism may be arranged to conform to a particular faceplate, a particular DIN unit, and/or a particular PED. Accordingly, a wide variety of ejection mechanisms are possible and contemplated. It is further noted that an ejection mechanism is not a requirement for all embodiments. Various embodiments of the assemblies described herein may rely solely on user force for insertion and removal of a PED into a docking port.

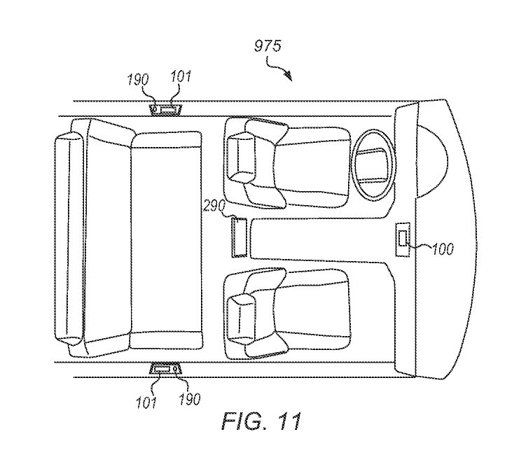

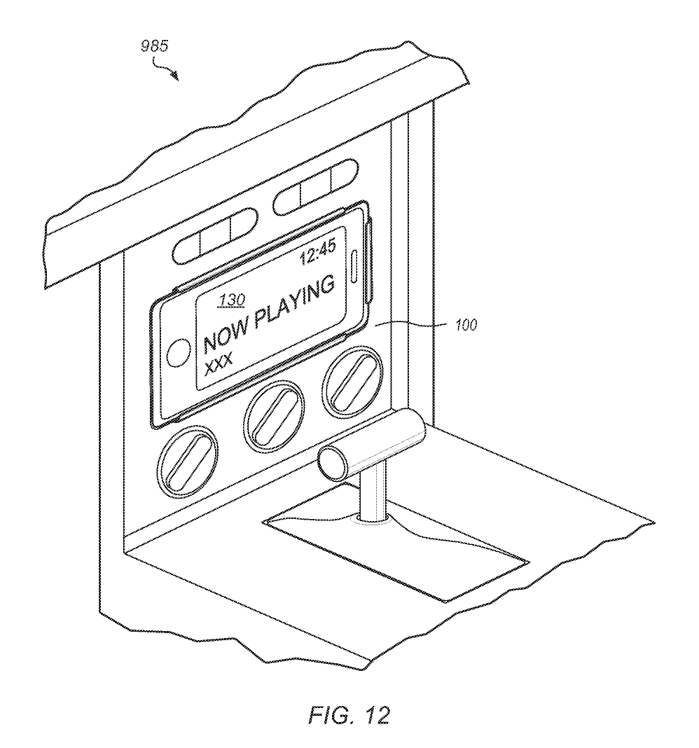

FIG. 11 is an overhead view of one embodiment of an automobile interior having multiple docking assemblies. In this embodiment, automobile interior 975 includes three separate instances of a docking assembly, docking assembly 100 in the dashboard of the vehicle, and two docking assemblies 101, one on each side of the rear seat. As an alternate location, docking assemblies 101 could also be located in the headrests (on the back side) of the two front seats instead of the locations shown.

Each of the rear seat docking assemblies 101 are accompanied by a headphone jack 190 in this embodiment. Each of docking assemblies 100 and 101 may be coupled to a vehicle electronic system, although their relative capabilities may vary by location.

In this particular example, docking assembly 100 in the dashboard of vehicle interior 975 may enable a PED 130 coupled thereto to act as a master, with the capability to override at least some selections made by PEDs 130 coupled to one or both of docking assemblies 101. For example, a PED 130 coupled to docking assembly 100 may retain control over audio that is output by speakers (not shown here) of a vehicle electronic system within the automobile in which automobile interior 975 is located. However, a user of a PED 130 coupled to a docking assembly 101 may still be able to control the audio output through headphones that may be coupled to a corresponding headphone jack 190. This may allow a user to watch video and listen to its corresponding audio while another user listens to music through speakers located in the vehicle interior.

In the embodiment shown, vehicle interior 975 also includes a video display unit 290. Control of the video display unit 290 may be initially provided to a PED 130 coupled to docking assembly 100, although such control may be transferred to a PED 130 in either one of docking assemblies 101. Video display unit 290 may be used for playback of video files stored on a PED 130, and may also be used for displaying navigation information, web browsing, reading emails, and so forth, per the capabilities of the controlling PED 130. Video display unit 290 may be implemented as an LCD (liquid crystal display), a plasma display, or any other suitable type of display. It is noted that additional video displays may be present in some embodiments, and embodiments having no video display are also possible and contemplated. Similarly, the number and location of docking assemblies 100 and 101 may vary from one vehicle embodiment to the next. The locations may includes (but are not limited to) headrests, backs of seats, a rear portion of a center console, interior side panels, and so forth.

An additional example of a PED 130 coupled to a docking assembly 100 in an automobile dashboard 985 is shown in FIG. 12. The location of PED 130 relative to a driver of an automobile in which dashboard 985 is located may provide for secure storage while the vehicle is moving, while also providing access to the driver or a passenger in a seat next to the driver. The easy access may allow a driver or passenger to utilize the full functionality of PED 130 while it is coupled to docking assembly 130. Furthermore, PED 130 may utilize portions of the vehicle electronic system (e.g., speakers, a video display unit) through hardwired connections that are achieved. The easy access to PED 130 (and thus the functionality it provides) may be achieved without compromising operator safety. When PED 130 is coupled to docking assembly 100 and secured therein, it may be visible and within easy reach of the vehicle operator, while risk of dropping PED 130 may be eliminated. Moreover, the chance of PED 130 being temporarily lost by slipping between or under a seat due to mishandling while the vehicle is in motion.

In the embodiment shown, PED 130 is nearly flush with the surfaces of docking assembly 100 when mounted therein. In general, the arrangement of a particular embodiment of docking assembly 100 may allow for the coupling of PED 130 to a vehicle electronic system, using hardwired connections, without the use of external accessories (e.g., such as FM transmitters or other wireless connections).

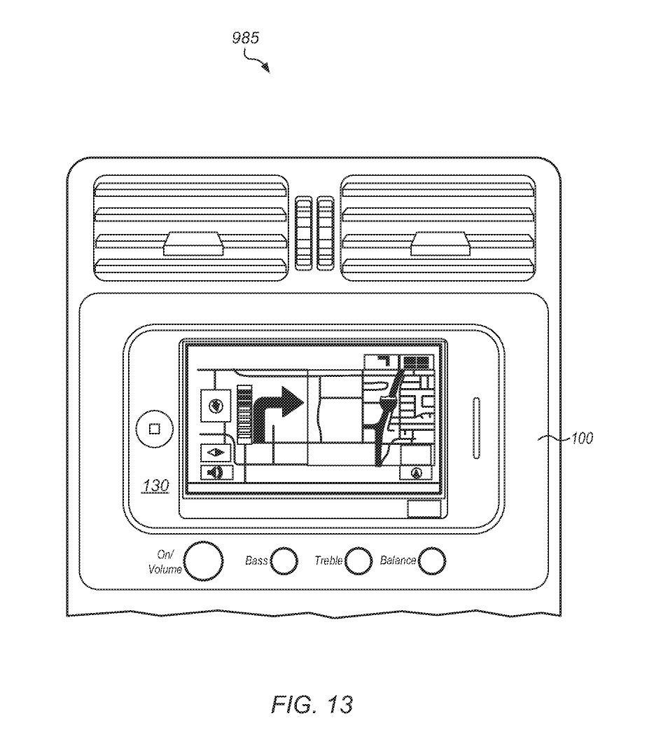

FIG. 13 illustrates a front view example of a PED 130 coupled to a docking assembly 100 in an automobile dashboard 985. The example shown in FIG. 13 may be similar to that of FIG. 13. However, in this particular embodiment, knobs are included for controlling the volume, bass, treble, and balance of the audio provided by the speakers of the vehicle electronic system 105 (not shown). These knobs may be coupled to a tone control circuit and/or audio transmission unit (e.g., tone control unit 240 or audio transmission unit 250 as discussed in various embodiments above). Accordingly, a user may adjust various sound characteristics using these knobs when utilizing PED 130 to provide audio to speakers in the vehicle. Thus, various embodiments of a docking assembly may be equipped with such knobs to enable an operator to adjust the sound characteristics. Embodiments of a docking assembly including additional manual controls (e.g., sliders for a graphic equalizer) are also possible and contemplated. Furthermore, embodiments without such knobs, wherein control of the audio signal characteristics is provided by PED 130, are also possible and contemplated. Embodiments where PED 130 controls the audio characteristics may provide similar tone control functions as those provided by the knobs discussed above, may provide a graphic equalizer function, and/or may provide processing to produce additional sound effects (e.g., echo, reverb, etc.).

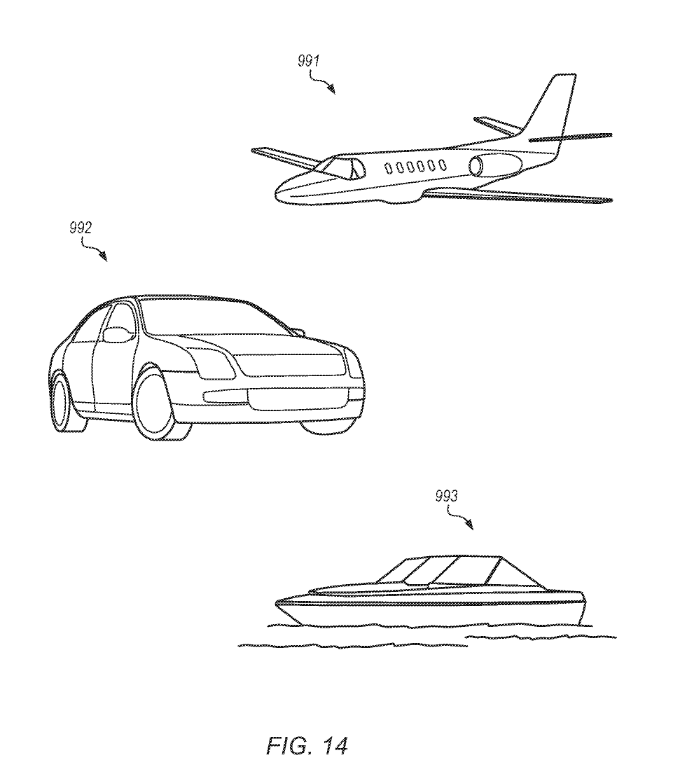

FIG. 14 is a perspective view of different vehicle types that may include an embodiment of a docking assembly according to one of the embodiments described above as well as variations thereof. A docking assembly according to any of the embodiments discussed above may be implemented in an aircraft 991, an automobile 992, or a boat 993. More generally, a docking assembly according to any of the embodiments discussed above may be implemented in any vehicle designed to travel on land, on water, or in the air. Thus, an aircraft according to a description herein may range from a small, private aircraft to a large, commercial aircraft, as well as those in between, and may additionally include various types of helicopters. A land vehicle according to the description herein may include a small automobile, a truck, a bus, a tractor, a motorcycle, and so forth. A boat according to the description herein may include a small motor or sail boat, a yacht, a cruise ship, or any other type of waterborne vessel.

The locations of a docking assembly within a particular vehicle may vary according to the vehicle and the needs of its operator(s) and passengers. As previously noted, the term ‘dashboard’ as used herein may refer to an instrument panel or other type of panel within reach of an operator. Accordingly, an embodiment of a docking assembly as disclosed herein may be implemented in a location within reach of a pilot of an aircraft, a driver or helmsman of a boat, or driver of an automobile. Furthermore, embodiments of docking assembly may also be placed in various locations of a vehicle within reach of passengers therein.

In some instances, the capabilities utilized by a particular embodiment of a PED 130 in a particular vehicle may be controlled by additional functionality in the vehicle electronic system. For example, an embodiment of a docking assembly in an aircraft is possible and contemplated wherein wide area communications functions (e.g., cellular telephone operation, internet access, etc.) of a PED 130 are inhibited when coupled to a docking assembly within. Such an embodiment may enable the use of audio and video playback functionality of a PED 130 if it is so configured. Furthermore, such an aircraft embodiment may be configured to inhibit all operation of a PED 130 when coupled to a docking assembly during critical operational times, such as takeoff and landing.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. A vehicle docking assembly comprising:
a housing unit including a first portion of a vehicle electronic system, the housing unit being suitable for mounting in a vehicle that includes a second portion of the vehicle electronic system, wherein the first portion of the vehicle electronic system includes at least one unit configured to be coupled to a corresponding unit of a second portion of a vehicle electronic system; and
a docking port coupled to the housing unit, the docking port including an electrical connector, wherein the docking port is configured to mechanically couple a portable electronic device to the housing unit and wherein the docking port is further configured to electrically couple the portable electronic device to the first portion of the vehicle electronic system;
wherein the first portion of the vehicle electronic system is configured to receive audio signals from the portable electronic device when the portable electronic device is electrically coupled thereto.

2. The vehicle docking assembly as recited in claim 1, wherein the housing unit is a DIN (Deutsches Institut für Normung) unit, wherein the DIN unit is one of the following:
single DIN unit;
a double DIN unit;
a 1.5 DIN unit.

3. The vehicle docking assembly as recited in claim 2, wherein the DIN unit is configured to be integrated into a dashboard of a vehicle.

4. The vehicle docking assembly as recited in claim 1, wherein the first portion of the vehicle electronic system includes an audio transmission circuit and a power charging circuit, wherein the audio transmission circuit is configured to receive audio signals from the portable electronic device and further configured to convey audio signals to an audio amplifier of the second portion of the electronic system, and wherein the power charging circuit is configured to charge a battery of the portable electronic device.

5. The vehicle docking assembly as recited in claim 4, wherein the audio transmission circuit includes an amplifier configured to amplify the audio signals received by the audio transmission circuit.

6. The vehicle docking assembly as recited in claim 4, wherein the first portion of the vehicle electronic system further includes a video transmission unit configured to receive video signals from the portable electronic device and further configured to convey video signals to a video display unit of the second portion of the vehicle electronic system.

7. The vehicle docking assembly as recited in claim 6, wherein the video transmission unit is configured to receive and process one or more of the following types of video signals:
composite video signals;
component video signals;
S-video signals;
digital video signals.

8. The vehicle docking assembly as recited in claim 4, wherein the first portion of the electronic system includes a tone control unit configured to receive control signals from the portable electronic device, wherein the tone control unit is controllable to change one or more characteristics of audio signals received by the audio transmission circuit.

9. The vehicle docking assembly as recited in claim 1, wherein the docking port includes a first faceplate configured to be detachable from the housing unit, the faceplate having a form factor corresponding to a first type of portable electronic device, and wherein the housing unit is further configured for coupling to a second faceplate having a form factor corresponding to a second type of portable electronic device.

10. The vehicle docking assembly as recited in claim 1, wherein the docking port includes a faceplate configured to receive a first adapter, the first adapter having a form factor corresponding to a first type of portable electronic device, wherein the first adapter is configured to enable the first type of portable electronic device to be electrically coupled to the first portion of the vehicle electronic system and mechanically coupled to the faceplate; and
wherein the faceplate is further configured to receive a second adapter having a form factor corresponding to a second type of portable electronic device different from the first type, wherein the second adapter is configured to enable the second type of portable electronic device to be electrically coupled to the first portion of the vehicle electronic system and mechanically coupled to the faceplate.

11. The vehicle docking assembly as recited in claim 1, further comprising an ejection mechanism configured to eject the portable electronic device from the vehicle docking assembly.

12. The vehicle docking assembly as recited in claim 1, wherein the portable electronic device includes a cellular telephone function and an audio file player function, and wherein the vehicle electronic system is configured to receive audio signals from the portable electronic device when the portable electronic device is performing either of the cellular telephone or audio file player functions.

13. The vehicle docking assembly as recited in claim 1, wherein the vehicle docking assembly is integrated into one or more of the following locations of a vehicle:
a headrest;
a seat back;
a center console;
an interior side panel.

14. An assembly comprising:
a vehicle electronic system having a first portion and a second portion coupled to the first portion;
a housing unit containing the first portion of a vehicle electronic system, wherein the housing unit is suitable for mounting in a vehicle; and
a docking port coupled to the housing unit, wherein the docking port is configured to electrically couple a portable electronic device to the vehicle electronic system and further configured to mechanically couple the portable electronic device to the housing unit;
wherein at least one functional unit of the first portion of the vehicle electronic system is configured to receive audio signals from the portable electronic device when the portable electronic device is electrically coupled to the vehicle electronic system.

15. The assembly as recited in claim 14, wherein the housing unit is one of the following:
a single DIN (Deutsches Institut für Normung) unit;
a double DIN unit;
a 1.5 DIN unit.

16. The assembly as recited in claim 14, wherein the first portion of the vehicle electronic system includes:
an audio transmission unit configured to receive the audio signals from the portable electronic device and further configured to transmit the audio signals to at least one other functional unit of the vehicle electronic system;
a tone control unit configured to change one or more characteristics of the audio signals, wherein the tone control unit is controllable by the portable electronic device when the portable electronic device is electrically coupled to first portion of the portable electronic system; and
a video transmission unit configured to receive video signals from the portable electronic device when the portable electronic device is coupled to the first portion of the vehicle electronic system.

17. The assembly as recited in claim 14, wherein the second portion of the vehicle electronic system includes:
an audio amplifier coupled to receive the audio signals from the audio transmission unit and configured to generate amplified audio signals based on the audio signals received from the audio transmission unit;
at least one speaker coupled to receive the amplified audio signals from the audio amplifier and configured to output audio based on the amplified audio signals; and
a video display unit coupled to receive video signals from the video transmission unit and configured to display video based on the video signals.

18. The assembly as recited in claim 17, wherein the video transmission unit is configured to receive and process one or more of the following types of signals:
composite video signals;
component video signals;
S-video signals.

19. The assembly as recited in claim 16, wherein the docking port is configured for receiving a portable electronic device configured to perform one or more of the following functions:
a cellular telephone function;
an internet access function;
an audio file playback function;
a video file player function;
a navigation function.

20. The assembly as recited in claim 19, wherein the audio transmission unit is configured to receive and process audio signals when the portable electronic device is coupled to the first portion of the vehicle electronic system and performing one of the following functions:
the cellular telephone function;
the audio file playback function.

21. The assembly as recited in claim 14, wherein the docking port is configured to accommodate a first type of portable electronic device having a first form factor, and further configured to accommodate a second type of portable electronic device having a second form factor that is different from the first form factor.

22. The assembly as recited in claim 14, wherein the first portion of the vehicle electronic system includes a charging circuit, wherein the charging circuit is configured to charge a battery of the portable electronic device when the portable electronic device is electrically coupled to the first portion of the vehicle electronic system.

23. The assembly as recited in claim 14, wherein instances of the vehicle assembly are located in one or more of the vehicle:
a dashboard;
a headrest;
a seat back;
a center console;
an interior side panel

24. A vehicle docking assembly comprising:
a housing unit including a first portion of a vehicle electronic system, the housing unit being suitable for mounting in a vehicle that includes a second portion of the vehicle electronic system, wherein the first portion of the vehicle electronic system includes at least one unit configured to be coupled to a corresponding unit of a second portion of a vehicle electronic system; and
a docking port located on a front portion of the housing unit, wherein the docking port includes a first connector and a second connector, wherein each of the first and second connectors is configured to mechanically couple and secure a portable electronic device to the front portion of the housing unit, and further configured to electrically couple the portable electronic device to the first portion of the vehicle electronic system.

25. The vehicle docking assembly as recited in claim 24, wherein the portable electronic device includes a headphone jack, wherein the first connector includes a pin suitable for insertion into the headphone jack, and wherein the second connector is a connector having multiple pins.

26. The vehicle docking assembly as recited in claim 25, wherein the second connector is a 30-pin connector.

27. The vehicle docking assembly as recited in claim 24, wherein the first portion of the vehicle electronic system includes a charging circuit configured to charge a battery of the portable electronic device.

28. The vehicle docking assembly as recited in claim 24, wherein the first portion of the vehicle electronic system includes an audio transmission unit configured to convey audio signals to the second portion of the vehicle electronic system.

29. The vehicle docking assembly as recited in claim 28, wherein the audio transmission unit comprises a plurality of wires coupled to receive audio signals from the portable electronic device and further coupled to convey the audio signals to the second portion of the vehicle electronic system.

30. The vehicle docking assembly as recited in claim 28, wherein the audio transmission unit includes an amplifier coupled to receive audio signals from the portable electronic device, wherein the amplifier is configured to amplify and convey the audio signals to the second portion of the vehicle electronic system.

31. The vehicle docking assembly as recited in claim 28, further comprising a tone control coupled to receive the audio signals and further coupled to convey the audio signals to the audio signals to the audio transmission unit, wherein the tone control unit is configured to alter one or more of the following characteristics of the audio signals:
bass;
treble;
balance.

32. The vehicle docking assembly as recited in claim 31, wherein the tone control unit is operable by one or more knobs located on the front portion of the housing unit.

33. The vehicle docking assembly as recited in claim 24, wherein the first portion of the vehicle electronic system includes a video transmission unit coupled to convey video signals to the second portion of the vehicle electronic system.

34. The vehicle docking assembly as recited in claim 33, wherein the video transmission unit comprises a plurality of wires coupled to receive video signals from the portable electronic device and further coupled to convey the video signals to the second portion of the vehicle electronic system.

35. The vehicle docking assembly as recited in claim 33, wherein the video transmission unit includes processing circuitry configured to adjust one or more of the following characteristics of the video signals:
brightness;
contrast;
color.

36. The vehicle docking assembly as recited in claim 24, wherein the housing unit is a DIN (Deutsches Institut für Normung) unit, wherein the DIN unit is one of the following:
single DIN unit;
a double DIN unit;
a 1.5 DIN unit.
